(19) United States
(12) Patent Application Publication
(10) Pub. No.: US 2006/0141675 A1
(43) Pub. Date: Jun. 29, 2006

(54) METHOD OF MANUFACTURING HEAT SPREADER HAVING VAPOR CHAMBER DEFINED THEREIN

(76) Inventors: Ching-Bai Hwang, Shenzhen (CN); Xi-Jian Zhu, Shenzhen (CN); Chih-Hao Yang, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/163,402

(22) Filed: Oct. 18, 2005

(30) Foreign Application Priority Data
Dec. 24, 2004 (TW) 093140458

(51) Int. Cl. H01L 21/48

(52) U.S. Cl. 438/124

(57) ABSTRACT

A method for manufacturing a vapor chamber-based heat spreader includes the following steps: (1) providing a mold, the mold having a surface; (2) electrodepositing a layer of metal coating on the surface of the mold; (3) removing the mold from the coating layer, wherein the coating layer defines therein a chamber; (4) filling a working fluid into the chamber of the coating layer and sealing the coating layer, to thereby form a vapor chamber-based heat spreader.

### FIELD OF THE INVENTION

The present invention relates to a method of manufacturing a heat spreader having a vapor chamber defined therein. The heat spreader can be suitably applied to remove heat from heat-generating components.

### DESCRIPTION OF RELATED ART

It is common knowledge that heat is produced during normal operations of a variety of electronic components, such as integrated circuit chips of computers. To ensure normal and safe operations, cooling devices such as heat sinks are often employed to dissipate the generated heat away from these electronic components. However, as the chips of computers decrease in size and increase in power, the heat sinks required to cool the chips have grown to have a much larger footprint than the chips. Generally, a heat sink is most effective when there is a uniform heat flux applied over an entire base of the heat sink. When a heat sink with a large base is attached to an integrated circuit chip with a much smaller contact area, there is significant resistance to the flow of heat to the other portions of the heat sink base which are not in direct contact with the chip.

Currently, an advantageous mechanism for overcoming the resistance to heat flow in a heat sink base is to attach a heat spreader to the base of the heat sink. A typical heat spreader includes a vacuum vessel defining therein a vapor chamber, and a working fluid contained in the chamber of the vessel. In most cases, a wick structure is provided inside the chamber, lining the inside walls of the vessel. As an integrated circuit chip is maintained in thermal contact with and transfers heat to the heat spreader, the working fluid contained in the chamber corresponding to the hot contacting location vaporizes into vapor. The vapor runs quickly to be full of the chamber, and wherever the vapor comes into contact with a cooler wall surface of the vessel, it will condense into liquid and release its latent heat of vaporization. The condensed liquid then returns back to the hot contacting location via capillary action of the wick structure, to thereby remove the heat generated by the chip. In the chamber of the heat spreader, the thermal resistance associated with the vapor spreading is negligible, thus providing an effective means of spreading the heat from a concentrated source to a large heat transfer surface.

Although the heat spreader has low thermal resistance to the flow of heat, the immaturity in manufacture of such a heat spreader has already become a limitation to its application in electronic industry for dissipating heat from electronic components. Soldering process is a typical method currently available for manufacturing a vapor chamber-based heat spreader. The soldering process requires two or more pieces of metal plate to be soldered together. However, the heat spreader made by this method is sometimes a little heavier than expected, since, according to the soldering requirements thereof, each piece of metal plate to be soldered in the soldering process is required to have a minimum wall thickness, which, in some cases, is larger than that is normally required. In addition, the reliability of the heat spreader made by the soldering process is also a problem. If the heat spreader is not hermetically sealed due to a defective soldering, it will gradually lose vacuum condition in the vapor chamber subject to a micro-leakage. Moreover, the soldering process basically cannot make a heat spreader with relatively complex structure.

In view of the above-mentioned disadvantages of the conventional soldering process, there is a need for a method which can manufacture a vapor-chamber-based heat spreader while overcoming these disadvantages.

### SUMMARY OF INVENTION

The present invention relates to a method for manufacturing a heat spreader having a vapor chamber defined therein. A preferred method of the present invention includes the following steps: (1) providing a mold, the mold having a surface; (2) electrodepositing a layer of metal coating on the surface of the mold; (3) removing the mold from the coating layer, wherein the coating layer defines therein a chamber corresponding to the mold; (4) filling a working fluid into the chamber of the coating layer via a hole of the coating layer and sealing the hole of the coating layer, to thereby form a vapor chamber-based heat spreader.

According to the preferred method of the present invention, the heat spreader is integrally made by electrodeposition, and therefore the weight of the heat spreader can be easily controlled into an acceptable range by controlling the thickness of the coating layer. By providing different molds, heat spreaders with different structures can be accordingly obtained. Further, the reliability of the heat spreader made by the preferred method is also improved since the heat spreader is integrally formed.

Other advantages and novel features of the present invention will become more apparent from the following detailed description of preferred embodiments when taken in conjunction with the accompanying drawings, in which:

### BRIEF DESCRIPTION PF DRAWINGS

FIG. 1 is a flow chart showing the main steps of a preferred method of the present invention, for manufacturing a vapor-chamber-based heat spreader;

FIG. 2 is a schematic, cross-sectional view of a device for making a mold in accordance with one embodiment of the preferred method of FIG. 1;

FIG. 3 is a side elevation view of the mold made by the device of FIG. 2;

FIG. 4 is a schematic, cross-sectional view of an electrodeposition bath for electrodepositing a layer of metal coating on an outer surface of the mold of FIG. 3;

FIG. 5 is a cross-sectional view of the coating layer made by the electrodeposition of FIG. 4, showing that the mold contained in the coating layer is removed from outlet holes of the coating layer;

FIG. 6 is an isometric view of the coating layer of FIG. 5, after the mold is removed therefrom;

FIG. 7 is a cross-sectional view of the coating layer taken along line VII-VII of FIG. 6;

FIG. 8 is a schematic, cross-sectional view of a mold provided in accordance with another embodiment of the preferred method of FIG. 1;

FIG. 9 is a cross-sectional view of the mold of FIG. 8, together with a layer of metal coating electrodeposited on an inner surface thereof;

FIG. 10 is an isometric view of a mold provided in accordance with a further embodiment of the preferred method of FIG. 1;

FIG. 11 is a schematic, cross-sectional view of an electrodeposition bath for electrodepositing a layer of metal coating on an outer surface of the mold of FIG. 10; and

FIG. 12 is an isometric view of a product made by the electrodeposition of FIG. 11.

### DETAILED DESCRIPTION

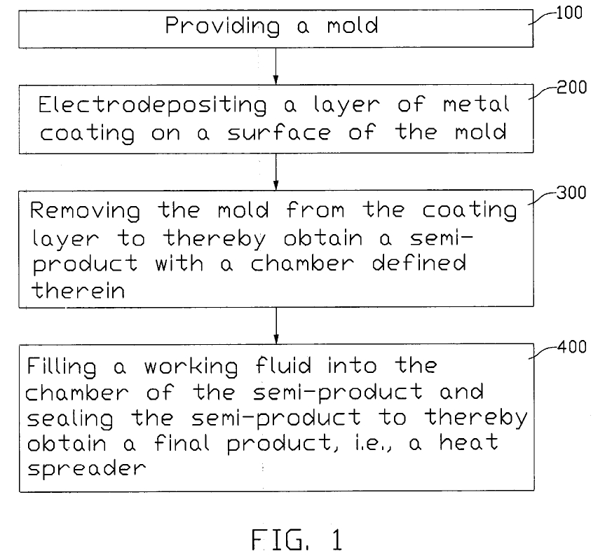

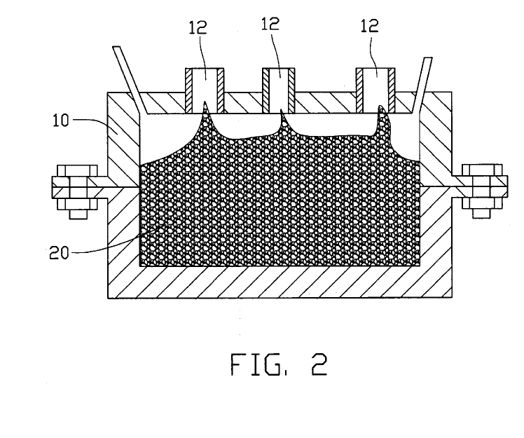

FIG. 1 is a flow chart showing the main steps that a preferred method of the present invention involves in manufacturing a vapor-chamber-based heat spreader. These steps include providing a mold (step 100), electrodepositing a layer of metal coating on a surface of the mold (step 200), removing the mold from the coating layer to thereby obtain a semi-product with a chamber defined therein (step 300) and filling a working fluid into the chamber of the semi-product and sealing the semi-product to thereby obtain a final product, i.e., a heat spreader (step 400). Specific examples for practicing the preferred method are shown in FIGS. 2-12.

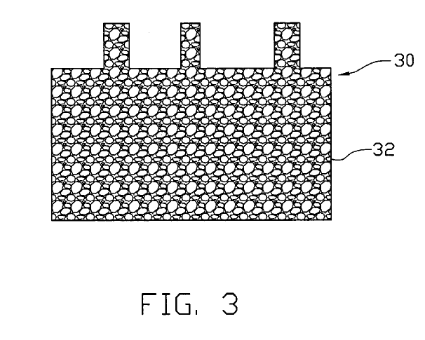

With reference to FIGS. 2-6, particular details for practice of the preferred method of FIG. 1 are given, in accordance with one embodiment of the present invention. Firstly, as shown in FIG. 2, a container 10 is provided and a kind of filling material 20 is filled into the container 10 in the form of slurry via inlet holes 12 defined in a sidewall (not labeled) of the container 10. The container 10 defines therein a cavity which has a configuration substantially the same as that of a vapor chamber of a heat spreader to be made. Then, the filling material 20 in the container 10 is solidified and the container 10 is removed, to thereby obtain a mold 30 comprised of the filling material 20, as shown in FIG. 3. In this embodiment, the filling material 20 is a slurry of small ceramic particles evenly mixed in a viscous binder. The solidification of the filling material 20 in the container 10 is typically accomplished by heating to dry the slurry. Since the mold 30 comprised of the ceramic filling material 20 is not electrically conductive, it is necessary to coat an electrically conductive layer 32 on an outer surface of the mold 30 before going to the electrodepositing step 200. Tops of three posts (not labeled) of the mold are not coated with the conductive layer 32.

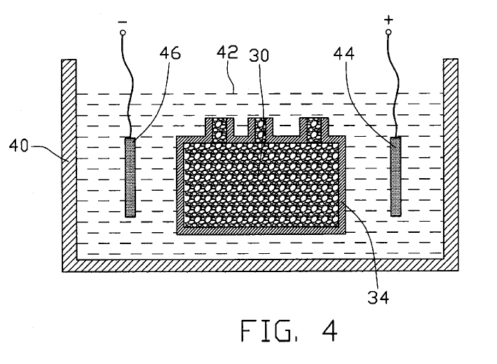

Then, the mold 30 is disposed into an electrodeposition bath 40 which contains an electrolyte 42, as shown in FIG. 4. The electrodeposition bath 40 includes an anode electrode 44 and a cathode electrode 46 which are located at opposite sides of the mold 30, respectively. After electrodepositing for a period of time, a layer of metal coating 34 is accordingly formed on the outer surface of the mold 30, except the tops of the three posts.

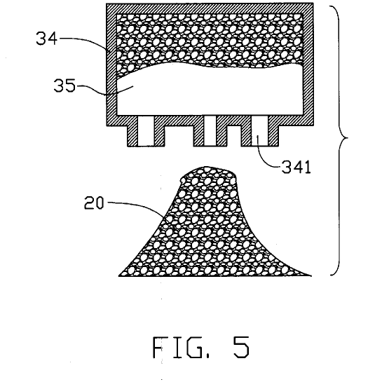

The coating layer 34, together with the mold 30 contained therein, is then taken out of the electrodeposition bath 40. The mold 30 is removed away from the coating layer 34 via its outlet holes 341 formed by the posts by, fox example, applying mechanical vibration thereto to thereby disintegrate the mold 30 into particles, whereby the mold 30 can be dumped out of the coating layer 34, as shown in FIG. 5.

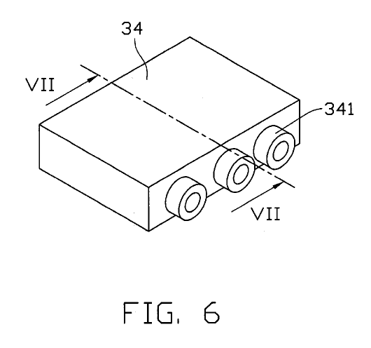

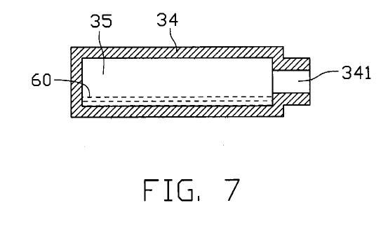

After the mold 30 is completely removed, a semi-product comprised of the coating layer 34 is therefore obtained, as shown in FIGS. 6-7. The semi-product defines therein a chamber 35, which is originally filled with the filling material 20. Then, a working fluid 60 is filled into the chamber 35 through the holes 341 of the semi-product. Finally the holes 341 is sealed hermetically by using conventional methods such as pressing, welding or soldering, to thereby obtain a final product, i.e., a vapor chamber-based heat spreader. Preferably, the original air in the chamber 35 is evacuated before the heat spreader is sealed, thereby forming a vacuum condition in the chamber 35. The working fluid 60 filled into the chamber 35 may be water, alcohol, methanol.

In accordance with the present invention, the filling material 20 is selected from such materials that can be easily removed after the coating layer 34 is electrodeposited on the mold 30. Therefore, the filling material 20 can also be plastic or polymeric material that is sensitive to temperature. In this situation, the mold 30 is made typically by filling the plastic or polymeric material into the container 10 when it is at a molten state. The material solidifies in the container 10 when it is cooled. Similarly, with respect to the mold-removing step 300, heating the coating layer 34 and the mold 30 above the melting temperature of the filling material 20 is an effective way to remove the filling material 20 away from the coating layer 34.

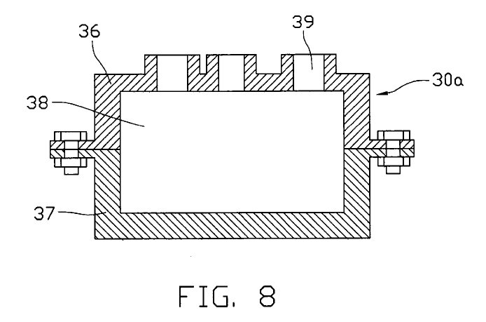

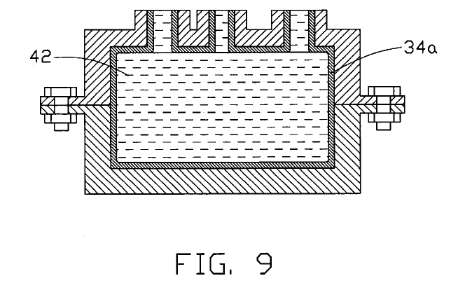

Another embodiment in accordance with the present invention for making a vapor chamber-based heat spreader is shown in FIGS. 8-9. In this embodiment, a mold 30a is provided which includes a top portion 36 and a bottom portion 37, as shown in FIG. 8. The mold 30a may be made of metal material. The top portion 36 is connected to the bottom portion 37 to thereby define a chamber 38 in the mold 30a. At least one inlet hole 39 is defined in the top portion 36 for filling an electrolyte 42 into the chamber 38, as shown in FIG. 9. In this embodiment, the mold 30a also functions as an electrodeposition bath. After electrodepositing for a period of time, a layer of metal coating 34a is therefore electrodeposited on an inner surface of the mold 30a. After the electrolyte 42 is discharged out of mold 30a and the mold 30a is opened, a semi-product comprised of the coating layer 34a is obtained. Then, the semi-product is filled with a working fluid and is hermetically sealed to finally form a vapor chamber-based heat spreader as described above.

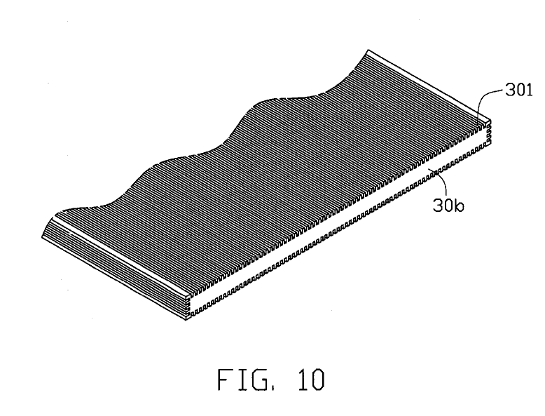

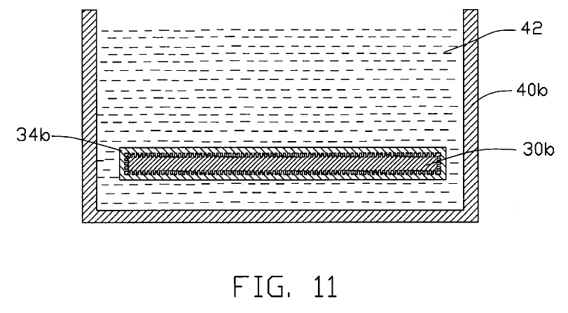

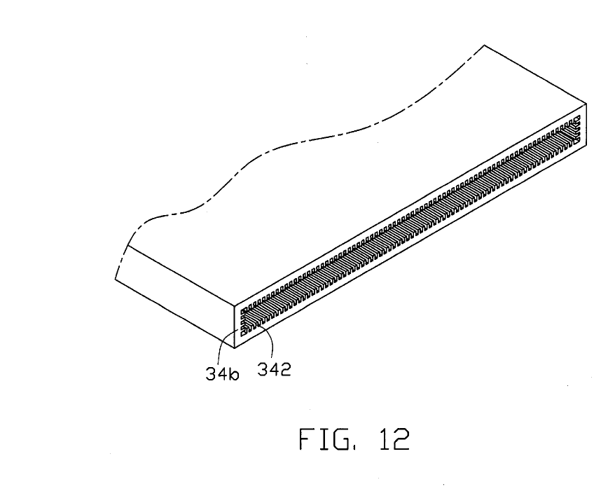

FIGS. 10-12 show a further embodiment of the present invention for practicing the preferred method of FIG. 1. Firstly, as shown in FIG. 10, a plate-type mold 30b is provided by using, for example, a process similar to the mold-making step as shown in FIG. 2. In this embodiment, the mold 30b has a plurality of spaced small protrusions 301 formed on an outer surface thereof. Then, the mold 30b is put into an electrodeposition bath 40b for electrodepositing a layer of metal coating 34b on the outer surface of the mold 30b, as shown in FIG. 11. After electrodepositing and removing the mold 30b, a semi-product comprised of the coating layer 34b is obtained, as shown in FIG. 12. The semi-product has a plurality of fine grooves 342 integrally formed along an inner surface of the coating layer 34b. The grooves 342, which are formed according to the pattern of the protrusions 301 of the mold 30b, will act as a wick structure for a vapor chamber-based heat spreader made from the semi-product.

According to the preferred method of the present invention, a heat spreader can be integrally made by electrodepositing, and the weight of the heat spreader can be easily controlled into an acceptable range since the wall thickness of the coating layer can be easily controlled by regulating the time period and voltage of the electrodeposition. By using different molds on which the coating layer is formed, heat spreaders with different structures can accordingly be obtained, even with some having relatively complex structures. Compared with the conventional soldering method, the reliability of the heat spreader made by the preferred method of the present invention is also improved since the heat spreader is integrally made and accordingly the micro-leakage problem is eliminated.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for manufacturing a heat spreader having a vapor chamber defined therein, the method comprising the steps of:
providing a mold, the mold having a surface;
electrodepositing a layer of metal coating on the surface of the mold;
removing the mold from the coating layer, wherein the coating layer defines therein a chamber corresponding to the mold; and
filling a working fluid into the chamber of the coating layer via a hole of the coating layer and sealing the hole of the coating layer.

2. The method of claim 1, wherein the mold is prepared by filling a kind of filling material into a container and then removing the container from the filling material after the filling material is solidified in the container.

3. The method of claim 2, wherein the filling material is a slurry of ceramic particles mixed in a viscous binder.

4. The method of claim 3, wherein the mold is removed away from the coating layer by applying mechanical vibration to the mold.

5. The method of claim 2, wherein the filling material is plastic or polymeric material.

6. The method of claim 5, wherein the mold is removed away from the coating layer by heating the mold.

7. The method of claim 1, wherein the surface on which the coating layer is formed is an outer surface of the mold.

8. The method of claim 7, wherein the mold has a plurality of protrusions formed on the outer surface thereof.

9. The method of claim 1, wherein the mold is a hollow one and the surface on which the coating layer is formed is an inner surface of the mold.

10. The method of claim 1, further comprising the step of coating an electrically conductive layer on the surface of the mold on which the coating layer is formed.

11. The method of claim 1, wherein the chamber is vacuumed before the chamber is sealed.

12. A method for forming a heat spreader having a vapor chamber therein, comprising the following steps:
forming a mold;
electrodepositing a layer of metal coating on the mold;
removing the mold from the layer of metal coating;
vacuuming a chamber of the layer of metal coating defined by the mold;
filling the chamber with liquid; and
sealing the chamber.

13. The method of claim 12, wherein the mold is formed of ceramic particles mixed in binder.

14. The method of claim 12, wherein the mold is formed of plastics.

15. The method of claim 12, wherein the mold is made of at least two separable portions connected together.

16. The method of claim 12, wherein the mold has a plurality of protrusions which forms a wick structure in the heat spreader after the mold is removed from the layer of metal coating.
